(19) United States
(12) Patent Application Publication
(10) Pub. No.: US 2006/0286953 A1
(43) Pub. Date: Dec. 21, 2006

(54) Signal measuring device

(76) Inventor: Hiroaki Takaoku, Tokyo (JP)

Correspondence Address: GREENBLUM & BERNSTEIN, P.L.C., 1950 ROLAND CLARKE PLACE, RESTON, VA, 20191, US

(21) Appl. No.: 10/556,354

(22) PCT Filed: May 12, 2004
(86) PCT No.: PCT/JP04/06711

§ 371 Date: Feb. 10, 2006

(30) Foreign Application Priority Data
May 15, 2003 (JP) 2003-137471

(51) Int. Cl. H04B 17/00; H03C 1/62

(52) U.S. Cl. 455/226.1; 455/115.2

(57) ABSTRACT

A signal measuring device controls the width of a signal for controlling frequency sweep, in accordance with a signal to be measured. The signal measuring device includes a local oscillator (10) for generating a local signal, a mixer (12) for mixing a signal to be measured with the local signal; a frequency sweep section (14) for sweeping the frequency of the local signal, and a sweep control section (30) for terminating the sweep when the presence section of the signal to be measured has terminated. The signal to be measured is a carrier in a burst and the spectrum of the carrier is to be measured. The width of the presence section of the signal to be measured may be changed. Even if changed, it is possible to control the width of the signal for controlling the frequency sweep, in accordance with the signal to be measured since the sweep is terminated when the presence section of the signal to be measured has terminated.

### TECHNICAL FIELD

The present invention relates to a measurement of frequency components of a signal to be measured, and more particularly relates to a frequency sweep upon the measurement.

### BACKGROUND ART

Conventionally, there has been known a device, which measures frequency components of a signal to be measured, as a spectrum analyzer. The spectrum analyzer carries out a frequency sweep while receiving the signal to be measured. By means of this frequency sweep, the spectrum analyzer measures the frequency components of the signal to be measured.

It is assumed that the signal to be measured is a carrier wave within a burst wave, and the frequency sweep continues while receiving the signal of the burst wave. In this case, there are measured a frequency component of the carrier wave within the burst wave as well as a frequency component of a modulated wave within the burst wave.

To measure the frequency component of the carrier wave within the burst wave, the frequency sweep is sometimes carried out only within sections where the carrier wave within the burst wave is present. This measurement is referred as gated sweep. According to the gated sweep, a gate signal which is High only within sections where the carrier wave is present is applied to a spectrum analyzer, and the frequency sweep is carried out when the gate signal is High.

It should be noted that a rise timing point of the gate signal and a width of a section where the gate signal is High may be further set for the gated sweep (refer to Patent document 1 (Japanese Laid-Open Patent Publication (Kokai) No. H5-60809)). The gated sweep carried out in this way is especially referred to as delay gated sweep.

However, according to the above prior art, the width of the section where the gate signal is High is fixed during the measurement. As a result, the prior art is not suitable for measuring a signal with a variable width of the carrier wave within the burst wave such as a signal with a variable slot width.

In view of the foregoing problems, it is an object of the present invention to control a width of a signal used to control the frequency sweep according to a signal to be measured.

### DISCLOSURE OF THE INVENTION

According to the present invention, a signal measuring device includes: a local signal generating unit that generates a local signal; a mixing unit that mixes a signal to be measured with the local signal; a frequency sweeping unit that sweeps the frequency of the local signal; and a sweep control unit that terminates the sweep upon a termination of a presence section of the signal to be measured.

According to the thus constructed present invention, a local signal generating unit generates a local signal. A mixing unit mixes a signal to be measured with the local signal. A frequency sweeping unit sweeps the frequency of the local signal. A sweep control unit that terminates the sweep upon a termination of a presence section of the signal to be measured.

According to the signal measuring device of the present invention, the sweep control unit may receive a trigger signal whose state changes upon the termination of the presence section of the signal to be measured.

According to the present invention, the signal measuring device, may further include an intermediate frequency filter that extracts a component within a predetermined frequency band from the mixing unit, wherein the trigger signal is generated based upon an output from the intermediate frequency filter.

According to the signal measuring device of the present invention, the sweep control unit may include a delay unit that delays the trigger signal, and a logical product output unit that takes and outputs a logical product of an output from the delay unit and the trigger signal, and whether the sweep is terminated or not may be determined according to the logical product output unit.

According to the signal measuring device of the present invention, the signal to be measured may be a carrier wave within a burst wave.

According to the signal measuring device of the present invention, the width of the presence sections of the carrier waves may be different from each other.

### BRIEF DESCRIPTION OF THE DRAWINGS

FIG. 1 is a block diagram showing a configuration of a spectrum analyzer (signal measuring device) 1 according the embodiment of the present invention;

FIG. 2 is a block diagram showing a configuration of the sweep control section 30;

FIG. 3 is a time chart showing an operation of the embodiment of the present invention;

FIG. 4 is a block diagram showing a configuration of the sweep control section 30 according to the variation of the embodiment of the present invention; and

FIG. 5 is a diagram showing a gate signal according to the variation of the embodiment of the present invention.

### BEST MODE FOR CARRYING OUT THE INVENTION

A description will now be given of an embodiment of the present invention with reference to drawings.

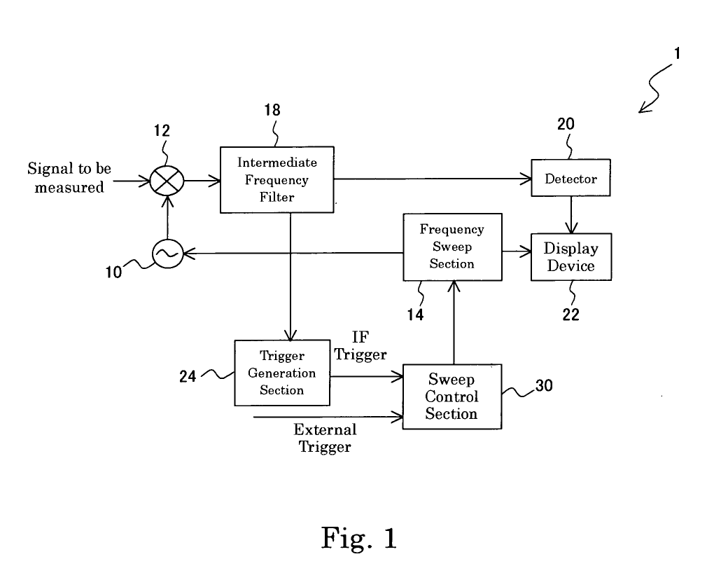

FIG. 1 is a block diagram showing a configuration of a spectrum analyzer (signal measuring device) 1 according the embodiment of the present invention. The spectrum analyzer (signal measuring device) 1 is provided with a local oscillator 10, a mixer (mixing means) 12, a frequency sweep section 14, an intermediate frequency filter 18, a detector 20, a display device 22, a trigger generation section 24, and a sweep control section 30.

The local oscillator 10 generates a local signal.

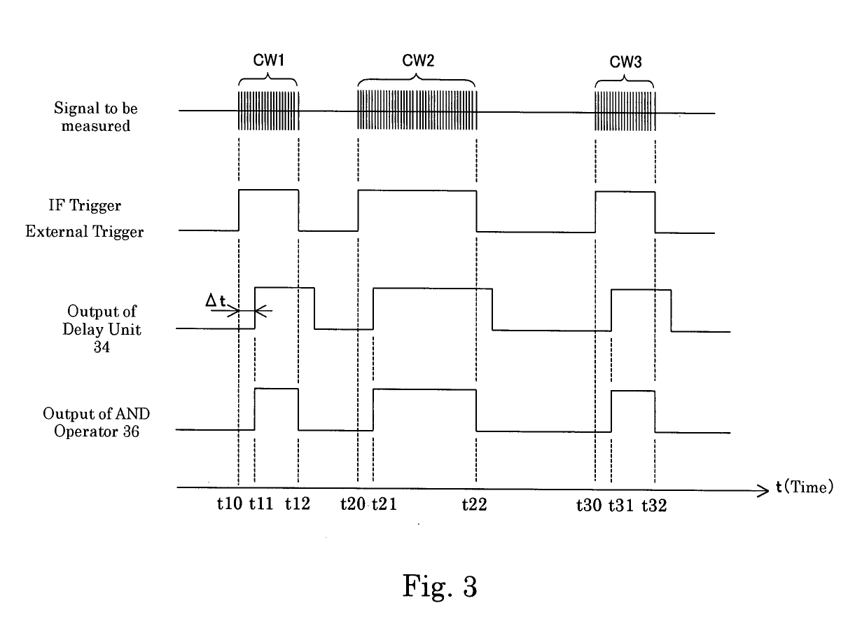

The mixer (mixing means) 12 is a multiplier which mixes a signal to be measured with the local signal, and outputs a result of the mixing. It should be noted that the signal to be measured includes carrier waves CW1, CW2, and CW3 within a burst wave as shown in FIG. 3. Moreover, widths of sections where the carrier waves CW1, CW2, and CW3 are present (respectively represented as t12-t10, t22-t20, and t32-t30) are different from one another. A purpose of the spectrum analyzer 1 is to measure and display a spectrum for the carrier waves CW1, CW2, and CW3 within the burst wave.

The frequency sweep section 14 sweeps the frequency of the local signal generated by the local oscillator 10. Specifically, the frequency sweep section 14 generates a sweep signal used to sweep the frequency of the local signal, and supplies the local oscillator 10 with the sweep signal. The local oscillator 10 is controlled by the applied sweep signal so as to sweep the frequency of the local signal.

The intermediate frequency filter 18 extracts a signal of a component within a predetermined frequency band from the output of the mixer 12.

The detector 20 detects the signal extracted by the intermediate frequency filter 18. As a result of the detection, power is obtained for respective frequencies of the signal to be measured.

The display device 22 displays an output of the detector 20. The display device 22 displays the spectrum of the signal to be measured with the power being assigned to the vertical axis, and the frequency being assigned to the horizontal axis.

The trigger generation section 24 generates an IF trigger signal, which is High within the sections where the carrier waves CW1, CW2, and CW3 within the burst wave are present, and is Low within sections where the carrier waves CW1, CW2, and CW3 are absent, based upon the output from the intermediate frequency filter 18 (by means of waveform shaping, for example).

The sweep control section 30 receives the IF trigger signal and an external trigger signal to control the frequency sweep section 14. It should be noted that the external trigger signal is a signal which is High within the sections where the carrier waves CW1, CW2, and CW3 within the burst wave are present, and is Low within the sections where the carrier waves CW1, CW2, and CW3 are absent.

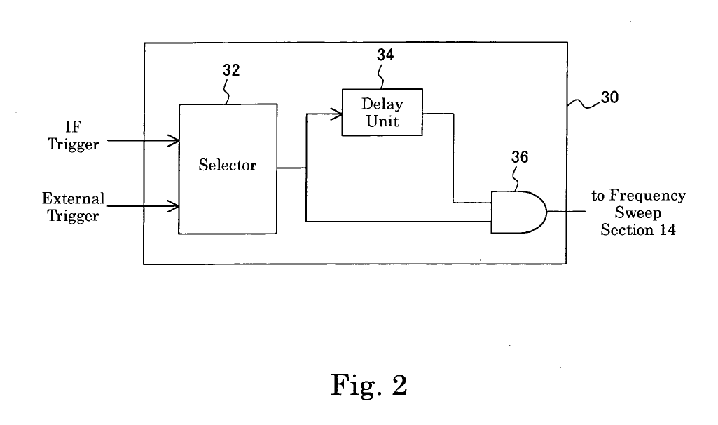

FIG. 2 is a block diagram showing a configuration of the sweep control section 30. The sweep control section 30 is provided with a selector 32, a delay unit 34, and an AND operator 36.

The selector 32 receives the IF trigger signal and the external trigger signal, and outputs either of them.

The delay unit 34 delays the output from the selector 32 by a predetermined period Δt.

The AND operator 36 takes logical product (AND) of the output from the selector 32 and an output from the delay unit 34, and outputs a result of the logical AND operation. Namely, the output of the AND operator 36 is High only if the output from the selector 32 and the output from the delay unit 34 are High at the same time. The output from the AND operator 36 is applied to the frequency sweep section 14. If the output from the AND operator 36 is High, the frequency sweep section 14 operates, and the frequency of the local signal is thus swept. If the output of the AND operator 36 is Low, the frequency sweep section 14 does not operate, and the frequency of the local signal is thus not swept.

A description will now be given of an operation of the embodiment of the present invention with reference to a time chart in FIG. 3.

First, the signal to be measured is the burst wave, and the purpose of the spectrum analyzer 1 is to measure and display the spectrum for the carrier waves CW1, CW2, and CW3 within the burst wave.

The signal to be measured is mixed with the local signal generated by the local oscillator 10 by the mixer 12. The intermediate frequency filter 18 extracts the signal of the component within the predetermined frequency band from the mixed signal. The trigger generation section 24 generates the IF trigger signal, which is High within the sections where the carrier waves CW1, CW2, and CW3 within the burst wave are present, and is Low within sections where the carrier waves CW1, CW2, and CW3 are absent, based upon the output from the intermediate frequency filter 18. There is also generated the external trigger signal which is High within the sections where the carrier waves CW1, CW2, and CW3 within the burst wave are present, and is Low within the sections where the carrier waves CW1, CW2, and CW3 are absent. The IF trigger signal and the external trigger signal are High within the sections from t10 to t12, t20 to t22, and t30 to t32.

The IF trigger signal and the external trigger signal are supplied to the selector 32 of the sweep control section 30, and either of them is output from the selector 32. The delay unit 34 delays the output from the selector 32 by the predetermined period Δt. The AND operator 36 takes the logical product (AND) of the output from the selector 32 and the output from the delay unit 34. The output of the delay unit 34 rises at time points t11(=t10+Δt), t21(=t20+Δt), and t31(=t30+Δt). The output of the AND operator 36 thus becomes High within sections from t11 to t12, t21 to t22, and t31 to t32. The frequency sweep section 14 consequently operates within the sections from t11 to t12, t21 to t22, and t31 to t32, and the frequency of the local signal is hence swept.

It should be noted that the sweep of the frequency of the local signal is terminated at the time points t12, t22, and t32 when the sections where the carrier waves CW1, CW2, and CW3 are respectively present are terminated. Moreover, it should be noted that the sweep of the frequency of the local signal starts at the time points t11, t21, and t31 delayed by Δt from the respective starts of the sections where the carrier waves CW1, CW2, and CW3 are respectively present.

The local signal is frequency-swept in this way. The signal extracted by the intermediate frequency filter 18 is then detected by the detector 20. As a result of the detection, the power is obtained for the respective frequencies of the signal to be measured. The display device 22 displays the output from the detector 20. The display device 22 displays the spectrum of the signal to be measured with the power being assigned to the vertical axis, and the frequency being assigned to the horizontal axis.

According to the embodiment of the present invention, even if the widths of the sections where the carrier waves CW1, CW2, and CW3 within the burst wave are present are different from one another, the sweep of the frequency of the local signal is terminated at the time points t12, t22, and t32 when the sections where the carrier waves CW1, CW2, and CW3 are respectively present are terminated. It is thus possible to prevent a spectrum of a modulated wave in sections other than the sections of the carrier waves CW1, CW2, and CW3 from being mixed with the spectrum of the signal to be measured, which is to be displayed upon the display device 22.

Moreover, the sweep of the frequency of the local signal starts at the time points delayed by Δt from the respective starts of the sections where the carrier waves CW1, CW2, and CW3 are respectively present. It is thus possible to prevent a transient response of the intermediate frequency filter 18 upon a start of the carrier waves CW1, CW2, and CW3 being input to the spectrum analyzer 1 from being mixed with the spectrum of the signal to be measured, which is to be displayed upon the display device 22.

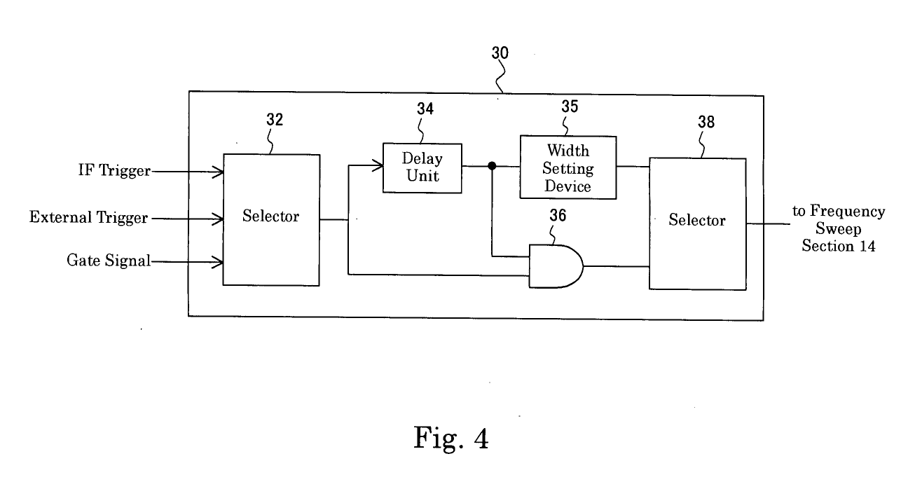

It should be noted that the widths of the sections within which the frequency sweep is carried out are not specified by a user of the spectrum analyzer 1, but is automatically determined according to the present embodiment. However, the user may want to specify the widths of the sections subject to the frequency sweep. A description will now be given of a variation corresponding to this case with reference to FIG. 4.

FIG. 4 is a block diagram showing a configuration of the sweep control section 30 according to the variation. The local oscillator 10, the mixer (mixing means) 12, the frequency sweep section 14, the intermediate frequency filter 18, the detector 20, the display device 22, and the trigger generation section 24 are similar to those of the above embodiment.

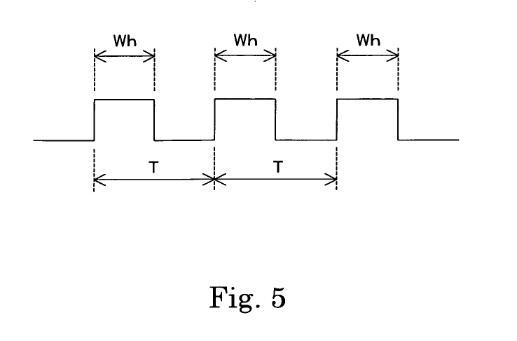

With reference to FIG. 4, the sweep control section 30 is provided with the selector 32, the delay unit 34, a width setting device 35, the AND operator 36, and a selector 38. The selector 32 receives the IF trigger signal, the external trigger signal, and a gate signal, and outputs any one of them. It should be noted that a rise of the gate signal is the time point at the start of the sections where the carrier waves CW1, CW2, and CW3 are present. In addition, as shown in FIG. 5, the gate signal repeats High and Low at a predetermined period T, and a width Wh where the gate signal is High is constant. The delay unit 34 is similar to that of the above embodiment. The width setting device 35 is provided for the user to set the width Wh where the gate signal is High. The AND operator 36 is similar to that of the above embodiment. The selector 38 selects an output from the width setting device 35 or the output from the AND operator 36, and outputs a result of the selection.

If the IF trigger signal or the external trigger signal is selected by the selector 32, the selector 38 selects the output from the AND operator 36. In this case, as in the above embodiment, the widths of the sections subject to the frequency sweep are automatically determined.

If the gate signal is selected by the selector 32, the selector 38 selects the output from the width setting device 35. In this case, the user can select Δt as well as the width Wh of the sections within which the frequency sweep is carried out.

Moreover, the above-described embodiment may be realized in the following manner. A computer is provided with a CPU, a hard disk, and a media (such-as a floppy disk (registered trade mark) and a CD-ROM) reader, and the media reader is caused to read a medium recording a program realizing the above-described respective components such as the sweep control section 30, thereby installing the program on the hard disk. This method may also realize the above-described functions.

1. A signal measuring device comprising:
a local signal generating means that generates a local signal;
a mixing means that mixes a signal to be measured with the local signal;
a frequency sweeping means that sweeps the frequency of the local signal; and
a sweep control means that terminates the sweep upon a termination of a presence section of the signal to be measured.

2. The signal measuring device according to claim 1, wherein said sweep control means receives a trigger signal whose state changes upon the termination of the presence section of the signal to be measured.

3. The signal measuring device according to claim 2, further comprising an intermediate frequency filter that extracts a component within a predetermined frequency band from said mixing means, wherein the trigger signal is generated based upon an output from said intermediate frequency filter.

4. The signal measuring device according to claim 2,
wherein said sweep control means comprises
a delay means that delays the trigger signal, and
a logical product output means that takes and outputs a logical product of an output from said delay means and the trigger signal, and
whether the sweep is terminated or not is determined according to said logical product output means.

5. The signal measuring device according to claim 1, wherein the signal to be measured is a carrier wave within a burst wave.

6. The signal measuring device according to claim 5, wherein widths of sections including the carrier waves differ from each other.

7. The signal measuring device according to claim 3,
wherein said sweep control means comprises
a delay means that delays the trigger signal, and
a logical product output means that takes and outputs a logical product of an output from said delay means and the trigger signal, and
whether the sweep is terminated or not is determined according to said logical product output means.

8. The signal measuring device according to claim 2, wherein the signal to be measured is a carrier wave within a burst wave.

9. The signal measuring device according to claim 3, wherein the signal to be measured is a carrier wave within a burst wave.

10. The signal measuring device according to claim 4, wherein the signal to be measured is a carrier wave within a burst wave.

11. The signal measuring device according to claim 7, wherein the signal to be measured is a carrier wave within a burst wave.

12. The signal measuring device according to claim 8, wherein widths of sections including the carrier waves differ from each other.

13. The signal measuring device according to claim 9, wherein widths of sections including the carrier waves differ from each other.

14. The signal measuring device according to claim 10, wherein widths of sections including the carrier waves differ from each other.

15. A signal measuring device comprising:
a local signal generator that generates a local signal;
a mixer that mixes a signal to be measured with the local signal;
a frequency sweep section that sweeps the frequency of the local signal; and
a sweep controller that terminates the sweep upon a termination of a presence section of the signal to be measured.

16. The signal measuring device according to claim 15, wherein the sweep controller receives a trigger signal whose state changes upon the termination of the presence section of the signal to be measured.

17. The signal measuring device according to claim 16, further comprising an intermediate frequency filter that extracts a component within a predetermined frequency band from the mixer, wherein the trigger signal is generated based upon an output from said intermediate frequency filter.

18. The signal measuring device according to claim 16,
wherein said sweep controller comprises
a delay unit that delays the trigger signal, and
a logical product output unit that takes and outputs a logical product of an output from said delay unit and the trigger signal, and
whether the sweep is terminated is determined according to said logical product output unit.

19. The signal measuring device according to claim 15, wherein the signal to be measured is a carrier wave within a burst wave.

20. The signal measuring device according to claim 19, wherein widths of sections including the carrier waves differ from each other.
